(19) United States
(12) Patent Application Publication
(10) Pub. No.: US 2023/0389365 A1
(43) Pub. Date: Nov. 30, 2023

(54) DISPLAY DEVICE

(71) Applicant: Samsung Display Co., LTD., Yongin-si (KR)

(72) Inventors: JINKOO CHUNG, Suwon-si (KR); JINGOO JUNG, Seongnam-si (KR)

(21) Appl. No.: 18/195,598

(22) Filed: May 10, 2023

(30) Foreign Application Priority Data
May 24, 2022 (KR) 10-2022-0063713

(51) Int. Cl. H10K 59/122; H10K 59/88; H10K 59/80; H10K 59/38

(52) U.S. Cl. CPC H10K 59/122; H10K 59/88; H10K 59/873; H10K 59/8792; H10K 59/38

(57) ABSTRACT

A display device includes a substrate including a display area including a first transmission area and a pixel area, and anon-display area including a second transmission area and a dummy pixel area, a light emitting element including a lower electrode disposed in the pixel area on the substrate, a dummy pattern disposed in the dummy pixel area on the substrate and including a same material as the lower electrode, a pixel defining layer disposed in the display area on the substrate and the lower electrode, where a first opening exposing an upper surface of the lower electrode is defined in the pixel defining layer, and a reflection control layer disposed in the non-display area on the substrate and the dummy pattern and including a same material as the pixel defining layer, where a second opening exposing an upper surface of the dummy pattern is defined in the reflection control layer.

This application claims priority to Korean Patent Application No. 10-2022-0063713, filed on May 24, 2022, and all the benefits accruing therefrom under 35 U.S.C. § 119, the content of which in its entirety is herein incorporated by reference.

### BACKGROUND

### 1. Field

Embodiments provide generally to display device. More particularly, embodiments relate to a display device for providing visual information.

### 2. Description of the Related Art

With the development of information technology, the importance of a display device, which is a connection medium between a user and information, has been highlighted. For example, the use of display devices such as liquid crystal display device (“LCD”), organic light emitting display device (“OLED”), plasma display device (“PDP”), quantum dot display device or the like is increasing.

Recently, a transparent display device having a transparent area and a pixel area and capable of transmitting an image of a target positioned on a rear surface of the display device has been developed.

### SUMMARY

In a transparent display device, a display area including the transparent area and the pixel area may be transparent, but a non-display area surrounding the display area may be opaque. In such a transparent display device, to manufacture the display device in which the non-display area is transparent may be difficult due to a difference in reflectance and transmittance between the display area and the non-display area.

Embodiments provide a display device with improved display quality.

A display device according to an embodiment of the disclosure includes a substrate including a display area including a first transmission area and a pixel area, and a non-display area including a second transmission area and a dummy pixel area, a light emitting element including a lower electrode disposed in the pixel area on the substrate, a dummy pattern disposed in the dummy pixel area on the substrate and including a same material as the lower electrode, a pixel defining layer disposed in the display area on the substrate and the lower electrode, where a first opening exposing an upper surface of the lower electrode is defined in the pixel defining layer, and a reflection control layer disposed in the non-display area on the substrate and the dummy pattern and including a same material as the pixel defining layer, where a second opening exposing an upper surface of the dummy pattern is defined in the reflection control layer.

In an embodiment, each of the pixel defining layer and the reflection control layer may include an organic insulating material.

In an embodiment, each of the pixel defining layer and the reflection control layer may further include at least one selected from a black pigment, a black dye, and a carbon black.

In an embodiment, an area of the first transmission area may be the same as an area of the second transmission area.

In an embodiment, a size of the first opening of the pixel defining layer may be different from a size of the second opening of the reflection control layer.

In an embodiment, the light emitting element may further include a light emitting layer disposed in the pixel area on the lower electrode and an upper electrode disposed on the pixel defining layer and the light emitting layer.

In an embodiment, the upper electrode may be entirely disposed in the display area and the non-display area.

In an embodiment, the upper electrode may be disposed in an area other than the first transmission area and the second transmission area.

In an embodiment, the display device may further include an encapsulation structure disposed in the display area and the non-display area on the upper electrode, where the encapsulation structure may include an inorganic encapsulation layer and an organic encapsulation layer.

In an embodiment, the display device may further include a first light blocking layer disposed in the display area on the encapsulation structure, where a first opening overlapping each of the first transmission area and the pixel area is defined in the first light blocking layer, and a first color filter layer disposed in the first opening of the first light blocking layer overlapping the pixel area.

In an embodiment, the display device may further include a second light blocking layer disposed in the non-display area on the encapsulation structure, where a second opening overlapping each of the second transmission area and the dummy pixel area is defined in the second light blocking layer, and a second color filter layer disposed in the second opening of the second light blocking layer overlapping the dummy pixel area.

In an embodiment, a size of the first opening of the first light blocking layer overlapping the pixel area may be different from a size of the second opening of the second light blocking layer overlapping the dummy pixel area.

In an embodiment, the display device may further include a buffer layer disposed in the display area and the non-display area on the substrate, an insulating layer disposed in the display area and the non-display area on the buffer layer, and a planarization layer disposed in the display area and the non-display area on the insulating layer.

In an embodiment, the planarization layer may include at least one selected from a photo sensitive polyimide (“PSPI”) and a siloxane-based resin.

In an embodiment, a first transmission window exposing an upper surface of the buffer layer positioned in the first transmission area may be defined through the insulating layer, the planarization layer and the pixel defining layer. In such an embodiment, a second transmission window exposing an upper surface of the buffer layer positioned in the second transmission area may be defined through the insulating layer, the planarization layer, and the reflection control layer.

In an embodiment, the dummy pattern may have an island shape in a plan view.

In an embodiment, each of the pixel area and the dummy pixel area may be repeatedly arranged in a first direction and a second direction orthogonal to the first direction.

In an embodiment, the first transmission area may be arranged on a side of the pixel area and the second transmission area may be arranged on a side of the dummy pixel area.

A display device according to an embodiment of the disclosure includes a substrate including a display area including a first transmission area and a pixel area, and a non-display area including a second transmission area and a dummy pixel area, where the second transmission area has a same area as an area of the first transmission area, a light emitting element including a lower electrode disposed in the pixel area on the substrate, a dummy pattern disposed in the dummy pixel area on the substrate and disposed in a same layer as the lower electrode, a pixel defining layer disposed in the display area on the substrate and the lower electrode and having a black color, and a reflection control layer disposed in the non-display area on the substrate and the dummy pattern, and disposed in a same layer as the pixel defining layer.

In an embodiment, a first opening exposing an upper surface of the lower electrode may be defined in the pixel defining layer and a second opening exposing an upper surface of the dummy pattern may be defined in the reflection control layer. A size of the first opening of the pixel defining layer may be different from a size of the second opening of the reflection control layer.

In a display device according to an embodiment of the disclosure, a dummy pattern including a same material as the lower electrode disposed in the display area may be disposed in the non-display area. In addition, a reflection control layer including a same material as a pixel defining layer disposed in the display area and having a black color may be disposed in a non-display area. Accordingly, the reflectance by external light of the display device in the display area may be similar to the reflectance by the external light of the display device in the non-display area.

In addition, in the display device according to an embodiment of the disclosure, an area of a first transmission area of the display area may be substantially the same as an area of a second transmission area of the non-display area. Accordingly, the transmittance of the display device in the display area may be similar to the transmittance of the display device in the non-display area.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment.

FIG. 2 is an enlarged view of the encircled portion “A” of FIG. 1.

FIG. 3 is a cross-sectional view taken along line I-I′ of FIG. 2.

FIGS. 4, 5, 6, 7, and 8 are cross-sectional views illustrating an embodiment of a method of manufacturing the display device of FIG. 3.

FIG. 9 is a cross-sectional view illustrating a display area and a non-display area of a display device according to an alternative embodiment.

FIG. 10 is a cross-sectional view illustrating a display area and a non-display area of a display device according to another alternative embodiment.

FIG. 11 is a block diagram illustrating an embodiment of an electronic device including the display device of FIG. 1.

FIG. 12 is a diagram illustrating an embodiment in which the electronic device of FIG. 11 is implemented as a television.

FIG. 13 is a diagram illustrating an embodiment in which the electronic device of FIG. 11 is implemented as a smartphone.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described in detail with reference to the accompanying drawings.

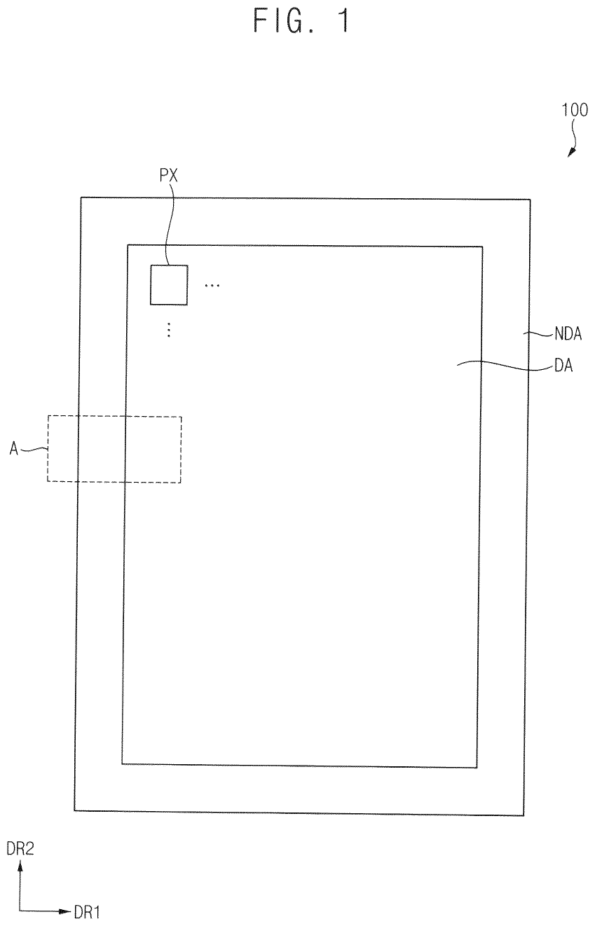

FIG. 1 is a plan view illustrating a display device according to an embodiment.

Referring to FIG. 1, a display device 100 according to an embodiment may include a display area DA and a non-display area NDA. The display area may be defined as an area capable of displaying an image by generating light or adjusting transmittance of light provided from a light source. The non-display area NDA may be defined as an area that does not display an image. The non-display area NDA may be positioned adjacent to the display area DA. In an embodiment, for example, the non-display area NDA may surround at least a portion of the display area DA.

A plurality of pixels PX may be disposed in the display area DA. In an embodiment, for example, each of the plurality of pixels PX may include a semiconductor element (e.g., a thin film transistor), a light emitting element (e.g., a light emitting diode) electrically connected to the semiconductor element, or the like. The light emitting element may receive a signal from the semiconductor element and emit light. As such, the display device 100 may display an image by emitting light from the plurality of pixels PX.

The plurality of pixels PX may be arranged in a matrix form along a first direction D1 and a second direction D2 intersecting the first direction D1. In an embodiment, for example, the first direction D1 and the second direction D2 may be orthogonal to each other.

A driver for driving the plurality of pixels PX may be disposed in the non-display area NDA. In an embodiment, for example, the driver may include a data driver, a gate driver, a light emitting driver, a power voltage generator, a timing controller, or the like. The plurality of pixels PX may emit light based on a signal received from the driver.

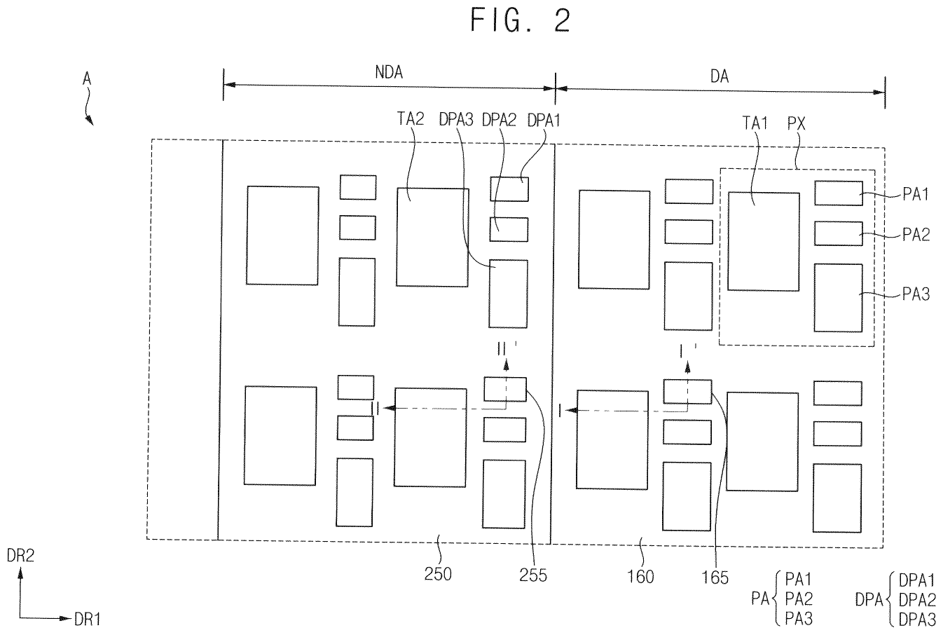

FIG. 2 is an enlarged view of the encircled portion “A” of FIG. 1.

Referring to FIGS. 1 and 2, an embodiment of the display area DA may include a plurality of first transmission areas TA1 and a plurality of pixel areas PA, and the non-display area NDA may include a plurality of second transmission areas TA2 and a plurality of dummy pixel areas DPA.

Each of the plurality of pixel areas PA may include a first pixel area PA1, a second pixel area PA2, and a third pixel area PA3. The first, second, and third pixel areas PA1, PA2, and PA3 may be repeatedly arranged along the first direction D1 and the second direction D2 intersecting the first direction D1. In an embodiment, for example, the first pixel area PA1 may be repeatedly arranged along the first direction D1 in a first row of the display area DA, the second pixel area PA2 may be repeatedly arranged along the first direction D1 in a second row of the display area DA adjacent to the first row, and the third pixel area PA3 may be repeatedly arranged along the first direction D1 in a third row of the display area DA adjacent to the second row.

Each of the first, second, and third pixel areas PA1, PA2, and PA3 may refer to an area in which the light emitted from the light emitting element is emitted to the outside of the display device 100. In an embodiment, for example, the first pixel area PA1 may emit light of a first color, the second pixel area PA2 may emit light of a second color, and the third pixel area PA3 may emit light of a third color. In an embodiment, the first color may be red, the second color may be green, and the third color may be blue. However, the configuration of the present disclosure is not limited thereto. In an alternative embodiment, for example, the first, second, and third pixel areas PA1, PA2, and PA3 may be combined to emit yellow, cyan, and magenta lights.

In an embodiment, an area of the third pixel area PA3 may be larger than an area of the second pixel area PA2. In such an embodiment, an area of the first pixel area PA1 may be the same as the area of the second pixel area PA2. However, the configuration of the present disclosure is not limited thereto, and the area of the first pixel area PA1 may be different from the area of the second pixel area PA2.

Each of the first, second, and third pixel areas PA1, PA2, and PA3 may have a triangular planar shape, a rectangular planar shape, a circular planar shape, a track-type planar shape, an elliptical planar shape, or the like. In an embodiment, each of the first, second, and third pixel areas PA1, PA2, and PA3 may have a rectangular planar shape. However, the configuration of the present disclosure is not limited thereto, and each of the first, second, and third pixel areas PA1, PA2, and PA3 may have one of various planar shapes.

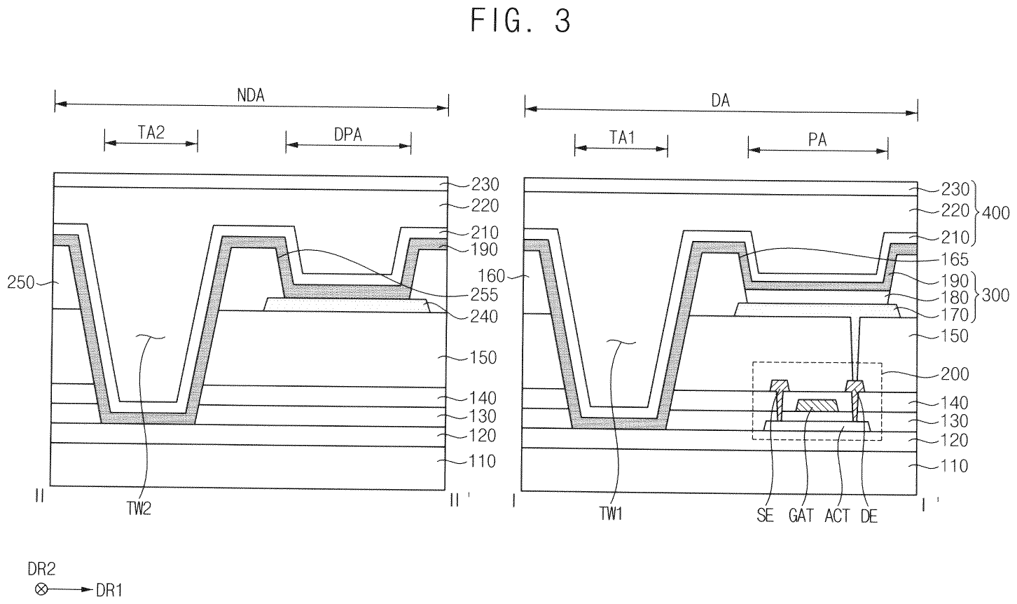

Light incident from an outside may be transmitted through each of the plurality of first transmission areas TA1. Accordingly, a transmission window (e.g., a first transmission window TW1 of FIG. 3) may be disposed in each of the plurality of first transmission areas TA1. Here, the pixel defining layer 160 may be disposed in a portion surrounding the first, second, and third pixel areas PA1, PA2, and PA3 and the plurality of first transmission areas TA1. A first opening 165 overlapping the pixel area PA may be defined in the pixel defining layer 160.

The plurality of first transmission areas TA1 may be repeatedly arranged along the first direction D1 and the second direction D2 intersecting the first direction D1. In an embodiment, for example, each of the plurality of first transmission areas TA1 may be positioned on a side (e.g., a left or right side) of the first, second, and third pixel areas PA1, PA2, and PA3.

One first transmission area TA1, one first pixel area PA1, one second pixel area PA2, and one third pixel area PA3 may collectively define one pixel PX.

Each of the plurality of dummy pixel areas DPA may not emit light of a specific color. That is, a light emitting element emitting light may not be disposed in each of the plurality of dummy pixel areas DPA.

Each of the plurality of dummy pixel areas DPA may include a first dummy pixel area DPA1, a second dummy pixel area DPA2, and a third dummy pixel area DPA3. In a plan view, each of the first, second, and third dummy pixel areas DPA1, DPA2, and DPA3 may be repeatedly arranged in the first direction D1 and the second direction D2. In an embodiment, for example, the first dummy pixel area DPA1 may be repeatedly arranged along the first direction D1 in a first row of the non-display area NDA, the second dummy pixel area DPA2 may be repeatedly arranged along the first direction D1 in a second row of the non-display area NDA adjacent to the first row, and the third dummy pixel area DPA3 may be repeatedly arranged along the first direction D1 in a third row of the non-display area NDA adjacent to the second row.

In an embodiment, an area of the third dummy pixel area DPA3 may be larger than an area of the first dummy pixel area DPA1 and an area of each of the second dummy pixel area DPA2. In such an embodiment, the area of the first dummy pixel area DPA1 may be the same as the area of the second dummy pixel area DPA2. However, the configuration of the present disclosure is not limited thereto, and the area of the first dummy pixel area DPA1 may be different from the area of the second dummy pixel area DPA2.

Each of the first, second, and third dummy pixel areas DPA1, DPA2, and DPA3 may have a triangular planar shape, a rectangular planar shape, a circular planar shape, a track-type planar shape, an elliptical planar shape, or the like. In an embodiment, each of the first, second, and third dummy pixel areas DPA1, DPA2, and DPA3 may have a rectangular planar shape. However, the configuration of the present disclosure is not limited thereto, and each of the first, second, and third dummy pixel areas DPA1, DPA2, and DPA3 may have one of various planar shapes.

Light incident from an outside may be transmitted through each of the plurality of second transmission areas TA2. Accordingly, a transmission window (e.g., a second transmission window TW2 of FIG. 3) may be disposed in each of the plurality of second transmission areas TA2. Here, the reflection control layer 250 may be disposed in a portion surrounding the first, second, and third dummy pixel areas DPA1, DPA2, and DPA3 and the plurality of second transmission areas TA2. A second opening 255 overlapping the dummy pixel area DPA may be defined in the reflection control layer 250.

The plurality of second transmission areas TA2 may be repeatedly arranged in the first direction D1 and in the second direction D2 intersecting the first direction D1. In an embodiment, for example, each of the plurality of second transmission areas TA2 may be positioned on a side (e.g., a left or right side) of the first, second, and third dummy pixel areas DPA1, DPA2, and DPA3.

An area of the first transmission area TA1 may be similar to an area of the second transmission area TA2. In an embodiment, the area of the first transmission area TA1 and the area of the second transmission area TA2 may be substantially the same as each other. In such an embodiment, the transmittance of the first transmission area TA1 may be similar to the transmittance of the second transmission area TA2. In an embodiment, for example, a difference between the transmittance of the first transmission area TA1 and the transmittance of the second transmission area TA2 may be about 10% or less. In such an embodiment, the difference between the transmittance of the first transmission area TA1 and the transmittance of the second transmission area TA2 may be about 5% or less. Accordingly, the transmittance of the display device 100 in the non-display area NDA may be similar to the transmittance of the display device 100 in the display area DA.

An area of the pixel area PA may be different from an area of the dummy pixel area DPA. That is, the size of the first opening 165 may be different from the size of the second opening 255. In an embodiment, an area of the dummy pixel area DPA may be smaller than an area of the pixel area PA. That is, the size of the second opening 255 may be smaller than the size of the first opening 165. In such an embodiment, the reflectance by external light of the display device 100 in the display area DA may be similar to the reflectance by external light of the display device 100 in the non-display area NDA. In an embodiment, for example, the difference between the reflectance by external light of the display device 100 in the display area DA and the reflectance by external light of the display device 100 in the non-display area NDA may be about 10% or less. In such an embodiment, the difference between the reflectance by external light of the display device 100 in the display area DA and the reflectance by external light of the display device 100 in the non-display area NDA may be about 3% or less.

As the display device 100 includes the plurality of first transmission areas TA1, the display device 100 may implement a transparent display device in the display area DA. In addition, as the display device 100 includes the plurality of second transparent areas TA2, the display device 100 may implement a transparent display device in the non-display area NDA.

FIG. 3 is a cross-sectional view taken along line I-I′ of FIG. 2. Particularly, FIG. 3 illustrates an embodiment of the display area DA and the non-display area NDA of the display device 100 of FIG. 2.

Referring to FIGS. 2 and 3, the display device 100 according to an embodiment of the disclosure may include a substrate 110, a buffer layer 120, a semiconductor element 200, a gate insulating layer 130, and an interlayer insulating layer 140, a planarization layer 150, a light emitting element 300, a dummy pattern 240, a pixel defining layer 160, a reflection control layer 250, and an encapsulation structure 400.

In such an embodiment, the semiconductor element 200 may include an active layer ACT, a gate electrode GAT, a source electrode SE, and a drain electrode DE, the light emitting element 300 may include a lower electrode 170, a light emitting layer 180, and an upper electrode 190, and the encapsulation structure 400 may include a first inorganic encapsulation layer 210, an organic encapsulation layer 220, and a second inorganic encapsulation layer 230.

In such an embodiment, as described above, the display device 100 may include the display area DA and the non-display area NDA. In such an embodiment where the display device 100 includes the display area DA and the non-display area NDA, the substrate 110 may also include the display area DA and the non-display area NDA.

The substrate 110 may include a transparent material or an opaque material. The substrate 110 may include or be formed of a transparent resin substrate. In an embodiment, for example, the transparent resin substrate may be a polyimide substrate or the like. In such an embodiment, the polyimide substrate may include a first organic layer, a first barrier layer, a second organic layer, or the like. Alternatively, the substrate 110 may include a quartz substrate, a synthetic quartz substrate, a calcium fluoride substrate, a fluorine-doped quartz substrate, a soda-lime substrate, a non-alkali glass substrate, or the like. These may be used alone or in combination with each other.

The buffer layer 120 may be disposed on the substrate 110. The buffer layer 120 may prevent diffusion of metal atoms or impurities from the substrate 110 to the semiconductor element 200. In an embodiment, where the surface of the substrate 110 is not uniform, the buffer layer 120 may serve to improve the flatness of the surface of the substrate 110. The buffer layer 120 may include an inorganic insulating material. In an embodiment, for example, the buffer layer 120 may include silicon oxide, silicon nitride, silicon oxynitride, or the like. These may be used alone or in combination with each other.

The active layer ACT may be disposed in the display area DA on the buffer layer 120. In an embodiment, the active layer ACT may be disposed in the pixel area PA of the display area DA. The active layer ACT may include a metal oxide semiconductor, an inorganic semiconductor (e.g., amorphous silicon, polysilicon, or the like) or an organic semiconductor. The active layer ACT may include a source region, a drain region, and a channel region positioned between the source region and the drain region.

The gate insulating layer 130 may be disposed in the display area DA and the non-display area NDA on the buffer layer 120. The gate insulating layer 130 may cover the active layer ACT in the display area DA. In an embodiment, for example, the gate insulating layer 130 may sufficiently cover the active layer ACT on the buffer layer 120, and may have a substantially flat upper surface without creating a step around the active layer ACT. Alternatively, the gate insulating layer 130 may cover the active layer ACT on the buffer layer 120 and may be disposed along a profile of the active layer ACT with a uniform thickness. In an embodiment, for example, the gate insulating layer 130 may include silicon oxide (SiOₓ), silicon nitride (SiNₓ), silicon carbide (SiCₓ), silicon oxynitride (SiOₓN_{y}), silicon oxycarbide (SiOₓC_{y}), or the like. These may be used alone or in combination with each other.

An opening exposing an upper surface of the buffer layer 120 positioned in the first transmission area TA1 may be defined in the gate insulating layer 130. In addition, an opening exposing an upper surface of the buffer layer 120 positioned in the second transmission area TA2 may be defined in the gate insulating layer 130.

The gate electrode GAT may be disposed in the display area DA on the gate insulating layer 130. In an embodiment, the gate electrode GAT may be disposed in the pixel area PA of the display area DA. The gate electrode GAT may overlap the channel region of the active layer ACT. In an embodiment, for example, the gate electrode GAT may include a metal, an alloy, a metal nitride, a conductive metal oxide, a transparent conductive material, or the like. These may be used alone or in combination with each other.

The interlayer insulating layer 140 may be disposed in the display area DA and the non-display area NDA on the gate insulating layer 130. The interlayer insulating layer 140 may cover the gate electrode GAT in the display area DA. In an embodiment, for example, the interlayer insulating layer 140 may sufficiently cover the gate electrode GAT on the gate insulating layer 130 and may have a substantially flat upper surface without creating a step around the gate electrode GAT. Alternatively, the gate insulating layer 130 may cover the gate electrode GAT on the gate insulating layer 130 and may be disposed along a profile of the gate electrode GAT with a uniform thickness. In an embodiment, for example, the interlayer insulating interlayer 140 may include silicon oxide, silicon nitride, silicon carbide, silicon oxynitride, silicon oxycarbide, or the like. These may be used alone or in combination with each other.

An opening exposing the upper surface of the buffer layer 120 positioned in the first transmission area TA1 may be defined in the interlayer insulating layer 140. In addition, an opening exposing the upper surface of the buffer layer 120 positioned in the second transmission area TA2 may be defined in the interlayer insulating layer 140.

The source electrode SE and a drain electrode DE may be disposed in the display area DA on the interlayer insulating layer 140. In an embodiment, each of the source electrode SE and the drain electrode DE may be disposed in the pixel area PA of the display area DA. The source electrode SE may be connected to the source region of the active layer ACT through a contact hole defined in a first portion of the gate insulating layer 130 and the interlayer insulating layer 140, and the drain electrode DE may be connected to the drain region of the active layer ACT through a contact hole defined in a second portion of the gate insulating layer 130 and the interlayer insulating layer 140. In an embodiment, for example, each of the source electrode SE and the drain electrode DE may include a metal, an alloy, a metal nitride, a conductive metal oxide, a transparent conductive material, or the like. These may be used alone or in combination with each other.

Accordingly, the semiconductor element 200 including the active layer ACT, the gate electrode GAT, the source electrode SE, and the drain electrode DE may be disposed in the display area DA on the substrate 110.

The planarization layer 150 may be disposed in the display area DA and the non-display area NDA on the interlayer insulating layer 140. The planarization layer 150 may sufficiently cover the source electrode SE and the drain electrode DE in the display area DA. The planarization layer 150 may have a relatively large thickness.

The planarization layer 150 may include an inorganic insulating material or an organic insulating material. In an embodiment, the planarization layer 150 may include an organic insulating material. In an embodiment, for example, the organic insulating material that can be used for the planarization layer 150 may include photoresist, polyacrylic resin, polyimide-based resin (e.g., photo sensitive polyimide (“PSPI”)), polyamide-based resin, a siloxane-based resin, an acrylic resin, an epoxy-based resin, or the like. These may be used alone or in combination with each other.

An opening exposing the upper surface of the buffer layer 120 positioned in the first transmission area TA1 may be defined in the planarization layer 150. In addition, an opening exposing the upper surface of the buffer layer 120 positioned in the second transmission area TA2 may be defined in the planarization layer 150.

The lower electrode 170 may be disposed in the display area DA on the planarization layer 150. In an embodiment, the lower electrode 170 may be disposed in the pixel area PA of the display area DA. The lower electrode 170 may be connected to the drain electrode DE through a contact hole defined in a portion of the planarization layer 150. Accordingly, the lower electrode 170 may be electrically connected to the semiconductor element 200. In an embodiment, for example, the lower electrode 170 may include a metal, an alloy, a metal nitride, a conductive metal oxide, a transparent conductive material, or the like. These may be used alone or in combination with each other. In an embodiment, for example, the lower electrode 170 may act as an anode.

The dummy pattern 240 may be disposed in the non-display area NDA on the planarization layer 150. In an embodiment, the dummy pattern 240 may be disposed in the dummy pixel area DPA of the non-display area NDA. In an embodiment, for example, the dummy pattern 240 may include a metal, an alloy, a metal nitride, a conductive metal oxide, a transparent conductive material, or the like. These may be used alone or in combination with each other. In an embodiment, the dummy pattern 240 may have an island shape in a plan view. In an alternative embodiment, the dummy pattern 240 may have a mesh shape in a plan view.

In an embodiment, the dummy pattern 240 may be disposed in (or directly on) a same layer as the lower electrode 170. In such an embodiment, the dummy pattern 240 may include a same material as the lower electrode 170.

The pixel defining layer 160 may be disposed in the display area DA on the planarization layer 150. The first opening 165 exposing an upper surface of the lower electrode 170 and overlapping the pixel area PA may be defined in the pixel defining layer 160. The pixel defining layer 160 may include an inorganic insulating material or an organic insulating material. In an embodiment, for example, the organic insulating material that can be used for the pixel defining layer 160 may include photoresist, polyacrylic resin, polyimide-based resin, polyamide-based resin, siloxane-based resin, acrylic-based resin, epoxy-based resin, or the like. These may be used alone or in combination with each other.

The pixel defining layer 160 may further include a light blocking material having a black color. In an embodiment, the pixel defining layer 160 may further include a black pigment, a black dye, carbon black, or the like. These may be used alone or in combination with each other.

The reflection control layer 250 may be disposed in the non-display area NDA on the planarization layer 150. The second opening 255 exposing an upper surface of the dummy pattern 240 and overlapping the dummy pixel area DPA may be defined in the reflection control layer 250. By adjusting the size of the second opening 255 of the reflection control layer 250, the reflectivity of the display device 100 by external light in the non-display area NDA may be reduced.

In an embodiment, for example, the reflection control layer 250 may include an organic insulating material such as a photoresist, a polyacrylic resin, a polyimide-based resin, a polyamide-based resin, a siloxane-based resin, an acrylic resin, an epoxy-based resin, or the like. These may be used alone or in combination with each other. In an embodiment, the reflection control layer 250 may further include a black pigment, a black dye, carbon black, or the like. These may be used alone or in combination with each other.

In an embodiment, the reflection control layer 250 may be disposed in a same layer as the pixel defining layer 160. In such an embodiment, the reflection control layer 250 may include a same material as the pixel defining layer 160.

An opening exposing the upper surface of the buffer layer 120 positioned in the first transmission area TA1 may be defined in the pixel defining layer 160. In addition, an opening exposing the upper surface of the buffer layer 120 positioned in the second transmission area TA2 may be defined in the reflection control layer 250.

In an embodiment, the opening defined in a first insulating layer (e.g., the gate insulating layer 130, the interlayer insulating layer 140, the planarization layer 150, and the pixel defining layer 160) and exposing the upper surface of the buffer layer 120 positioned in the first transmission area TA1 may correspond to the first transmission window TW1. In addition, the opening defined in a second insulating layer (e.g., the gate insulating layer 130, the interlayer insulating layer 140, the planarization layer 150, and the reflection control layer 250) and exposing the upper surface of the buffer layer 120 positioned in the second transmission area TA2 may correspond to the second transmission window TW2.

The light emitting layer 180 may be disposed in the pixel area PA on the lower electrode 170. In an embodiment, the light emitting layer 180 may be disposed in the first opening 165 of the pixel defining layer 160. The light emitting layer 180 may be formed using at least one selected from light emitting materials capable of emitting different color lights (i.e., red light, green light, blue light, or the like) according to the type of the pixel area PA. Alternatively, the light emitting layer 180 may emit white light as a whole by stacking a plurality of light emitting materials capable of generating light of different colors such as red light, green light, and blue light.

The upper electrode 190 may be disposed in the display area DA on the pixel defining layer 160 and the light emitting layer 180. The upper electrode 190 may extend from the display area DA to the non-display area NDA and may be disposed on the reflection control layer 250 and the dummy pattern 240. That is, the upper electrode 190 may be entirely disposed in the display area DA and the non-display area NDA. In an embodiment, for example, the upper electrode 190 may include a metal, an alloy, a metal nitride, a conductive metal oxide, a transparent conductive material, or the like. These may be used alone or in combination with each other. In an embodiment, for example, the upper electrode 190 may act as a cathode.

Accordingly, the light emitting element 300 including the lower electrode 170, the light emitting layer 180, and the upper electrode 190 may be disposed in the display area DA on the substrate 110.

The encapsulation structure 400 may be disposed on the upper electrode 190. The encapsulation structure 400 may be entirely disposed in the display area DA and the non-display area NDA. The encapsulation structure 400 may include at least one inorganic encapsulation layer and at least one organic encapsulation layer.

The encapsulation structure 400 may block the inflow of impurities from the outside into the light emitting element 300 and may protect the light emitting element 300 from the outside. The encapsulation structure 400 may have a flat upper surface over the display area DA and the non-display area NDA.

The encapsulation structure 400 may include the first inorganic encapsulation layer 210 disposed on the upper electrode 190, the organic encapsulation layer 220 disposed on the first inorganic encapsulation layer 210, and the second inorganic encapsulation layer 230 disposed on the organic encapsulation layer 220. Each of the first inorganic encapsulation layer 210 and the second inorganic encapsulation layer 230 may reduce or substantially block penetration of impurities such as oxygen and moisture into the light emitting element 300.

The organic encapsulation layer 220 may improve the sealing properties of the encapsulation structure 400, may relieve internal stress of the first inorganic encapsulation layer 210 and the second inorganic encapsulation layer 230, and may provide a flat upper surface to the second inorganic encapsulation layer 230. In an embodiment, for example, each of the first inorganic encapsulation layer 210 and the second inorganic encapsulation layer 230 may include silicon oxide, silicon nitride, silicon oxynitride, or the like. These may be used alone or in combination with each other. The organic encapsulation layer 220 may include a cured polymer such as polyacrylate.

In the display device 100 according to an embodiment of the disclosure, the dummy pattern 240 including a same material as the lower electrode 170 disposed in the display area DA may be disposed in the non-display area NDA. In such an embodiment, the reflection control layer 250 disposed in the display area DA and including the same material as the pixel defining layer PDL having a black color may be disposed in the non-display area NDA. Accordingly, the reflectance (i.e., the specular component included (“SCI”) reflectance and the specular component excluded (“SCE”) reflectance) due to external light of the display device 100 in the display area DA may be similar to the reflectance by external light of the display device 100 in the non-display area NDA. In such an embodiment, the reflectance (i.e., the SCE reflectance) of the display device 100 by external light in the display area DA and the non-display area NDA may be reduced.

In addition, in the display device 100 according to an embodiment of the disclosure, the area of the first transmission area TA1 of the display area DA may be substantially the same or similar as the area of the second transmission area TA2 of the non-display area. Accordingly, the transmittance of the display device 100 in the display area DA may be similar to the transmittance of the display device 100 in the non-display area NDA.

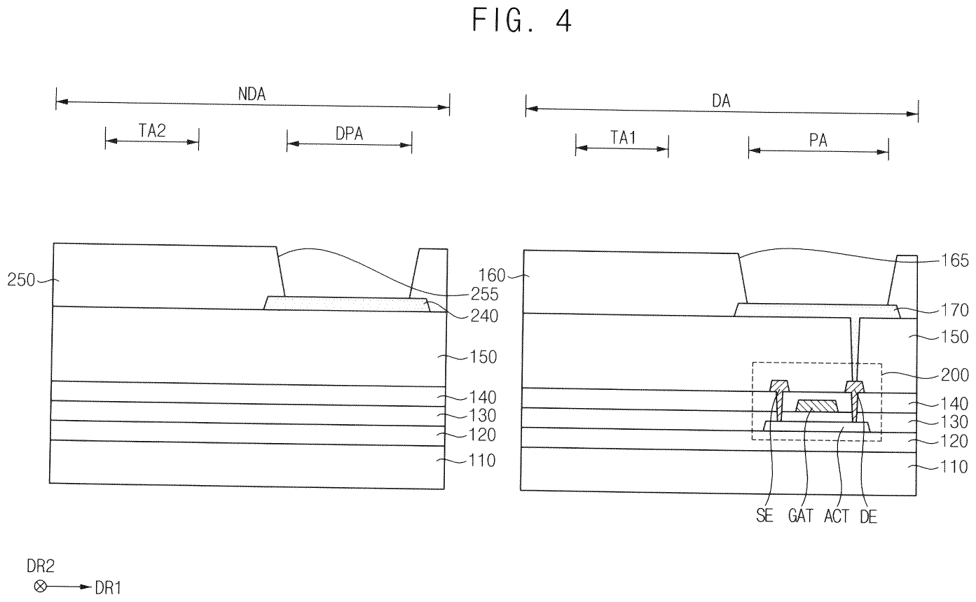

FIGS. 4, 5, 6, 7, and 8 are cross-sectional views illustrating an embodiment of a method of manufacturing the display device of FIG. 3.

Referring to FIG. 4, in an embodiment of a method of manufacturing the display device, the buffer layer 120 may be provided or formed in the display area DA and the non-display area NDA on the substrate 110. The substrate 110 may include a transparent material or an opaque material. The buffer layer 120 may include or be formed of silicon oxide, silicon nitride, or the like.

The active layer ACT may be provided or formed in the pixel area PA on the buffer layer 120. In an embodiment, for example, the active layer ACT may be formed using a metal oxide semiconductor, an inorganic semiconductor, or an organic semiconductor.

The gate insulating layer 130 may be provided or formed in the display area DA and the non-display area NDA on the buffer layer 120. The gate insulating layer 130 may be formed to cover the active layer ACT in the display area DA. In an embodiment, for example, the gate insulating layer 130 may be formed using silicon oxide, silicon nitride, or the like.

The gate electrode GAT may be provided or formed in the pixel area PA on the gate insulating layer 130. The gate electrode GAT may be formed to overlap a central portion of the active layer ACT. In an embodiment, for example, the gate electrode GAT may be formed using a metal, an alloy, and the like.

The interlayer insulating layer 140 may be provided or formed in the display area DA and the non-display area NDA on the gate insulating layer 130. The interlayer insulating layer 140 may be formed to cover the gate electrode GAT in the display area DA. In an embodiment, for example, the interlayer insulating layer 140 may be formed using silicon oxide, silicon nitride, or the like.

The source electrode SE and the drain electrode DE may be provided or formed in the pixel area PA on the planarization layer 150. In such an embodiment, a first contact hole exposing a source region of the active layer ACT may be formed by removing a first portion of the gate insulating layer 130 and the interlayer insulating layer 140. A second contact hole exposing a drain region of the active layer ACT may be formed by removing a second portion of the gate insulating layer 130 and the interlayer insulating layer 140. Then, the source electrode SE filling the first contact hole may be formed, and the drain electrode DE filling the second contact hole may be provided or formed. In an embodiment, for example, each of the source electrode SE and the drain electrode DE may be formed using a metal, an alloy, a conductive metal oxide, or the like.

The planarization layer 150 may be provided or formed in the display area DA and the non-display area MDA on the interlayer insulating layer 140. The planarization layer 150 may be formed to sufficiently cover the source electrode SE and the drain electrode DE. In an embodiment, for example, the planarization layer 150 may be formed using a photosensitive polyimide-based resin, a siloxane-based resin, or the like. A planarization process may be performed on the upper surface of the planarization layer 150. In an embodiment, an upper surface of the planarization layer 150 may be planarized by a chemical mechanical polishing (“CMP”) process. Accordingly, reflectance due to external light of the display device 100 (i.e., the SCE reflectance) may be reduced in the non-display area NDA and the display area DA.

The lower electrode 170 may be provided or formed in the pixel area PA on the planarization layer 150. In such an embodiment, a contact hole exposing the upper surface of the drain electrode DE may be formed by removing a portion of the planarization layer 150. Then, the lower electrode 170 filling the contact hole may be formed. In an embodiment, for example, the lower electrode 170 may be formed using a metal, an alloy, a conductive metal oxide, or the like.

The dummy pattern 240 may be provided or formed in the dummy pixel area DPA on the planarization layer 150. The dummy pattern 240 may be formed using a same material as the lower electrode 170. In such an embodiment, the dummy pattern 240 may be simultaneously formed with the lower electrode 170 through a same process.

The pixel defining layer 160 may be provided or formed in the display area DA on the planarization layer 150. The first opening 165 exposing the upper surface of the lower electrode 170 may be defined in the pixel defining layer 160. In an embodiment, for example, the pixel defining layer 160 may be formed using an organic insulating material.

The reflection control layer 250 may be provided or formed in the non-display area NDA on the planarization layer 150. The second opening 255 exposing the upper surface of the dummy pattern 240 may be defined in the reflection control layer 250. The reflection control layer 250 may be formed using a same material as the pixel defining layer 160. In other words, the reflection control layer 250 may be simultaneously formed with the pixel defining layer 160 through a same process.

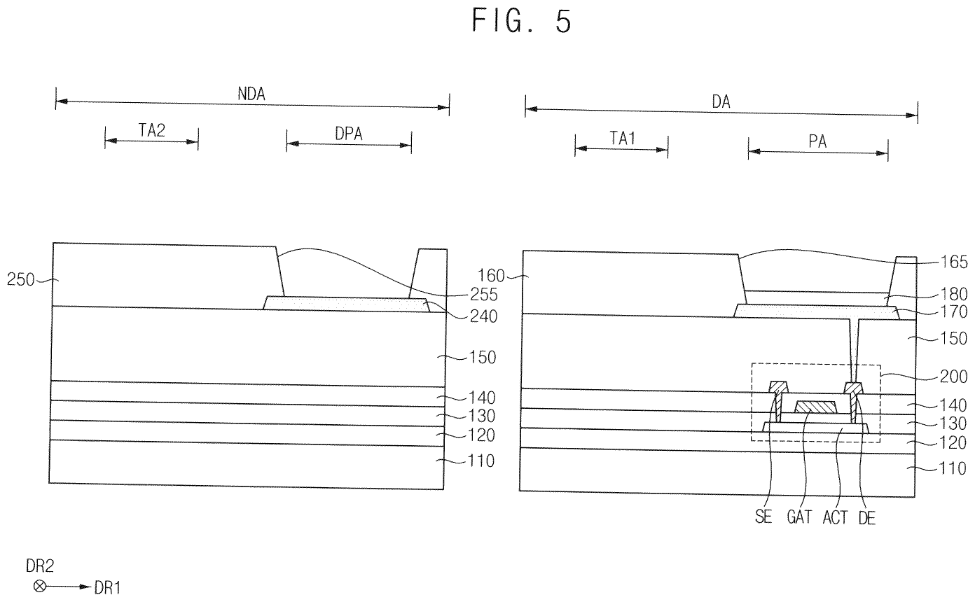

Referring to FIG. 5, the light emitting layer 180 may be provided or formed on the lower electrode 170. In an embodiment, the light emitting layer 180 may be formed in the first opening 165 of the pixel defining layer 160. The light emitting layer 180 may be formed using at least one of light emitting materials capable of emitting red light, green light, blue light, or the like depending on the type of the pixel area PA.

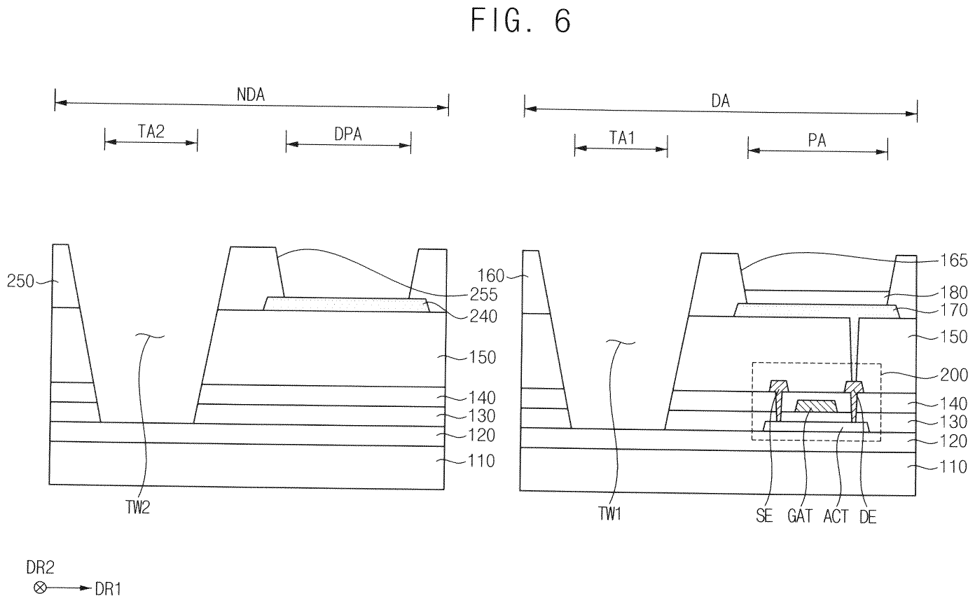

Referring to FIG. 6, a first opening may be formed by removing a portion of the gate insulating layer 130, the interlayer insulating layer 140, the planarization layer 150, and the pixel defining layer 160 positioned in the first transmission area TA1. The first opening may correspond to the first transmission window TW1. In addition, a second opening may be formed by removing a portion of the gate insulating layer 130, the interlayer insulating layer 140, the planarization layer 150, and the reflection control layer 250 positioned in the second transmission area TA2. The second opening may correspond to the second transmission window TW2.

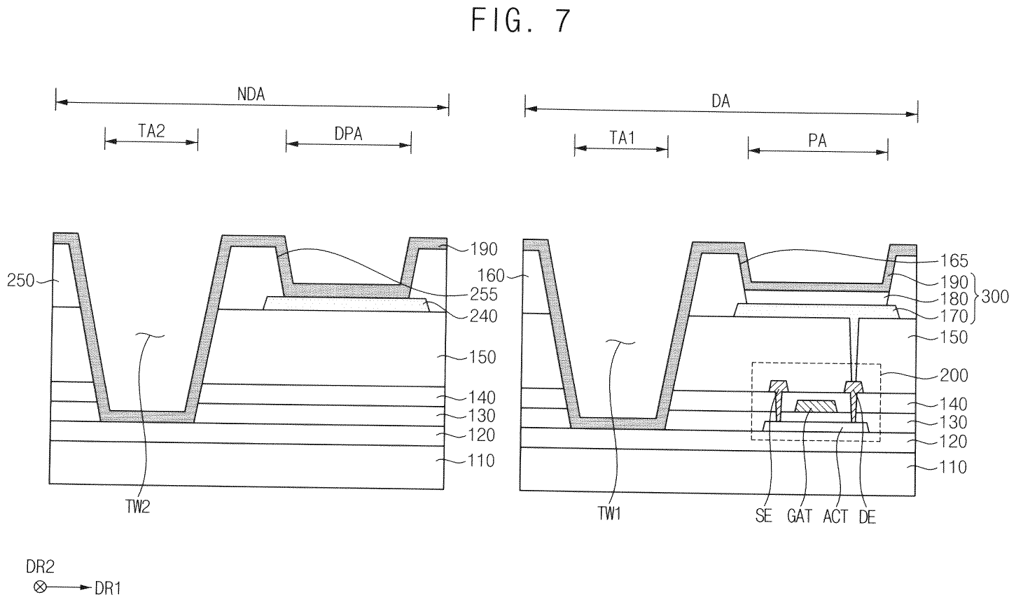

Referring to FIG. 7, the upper electrode 190 may be provided or formed on the pixel defining layer 160, the light emitting layer 180, the reflection control layer 250, and the dummy pattern 240. In an embodiment, the upper electrode 190 may be entirely formed in the display area DA and the non-display area NDA. In an embodiment, for example, the upper electrode 190 may be formed using a metal, an alloy, a conductive metal oxide, or the like.

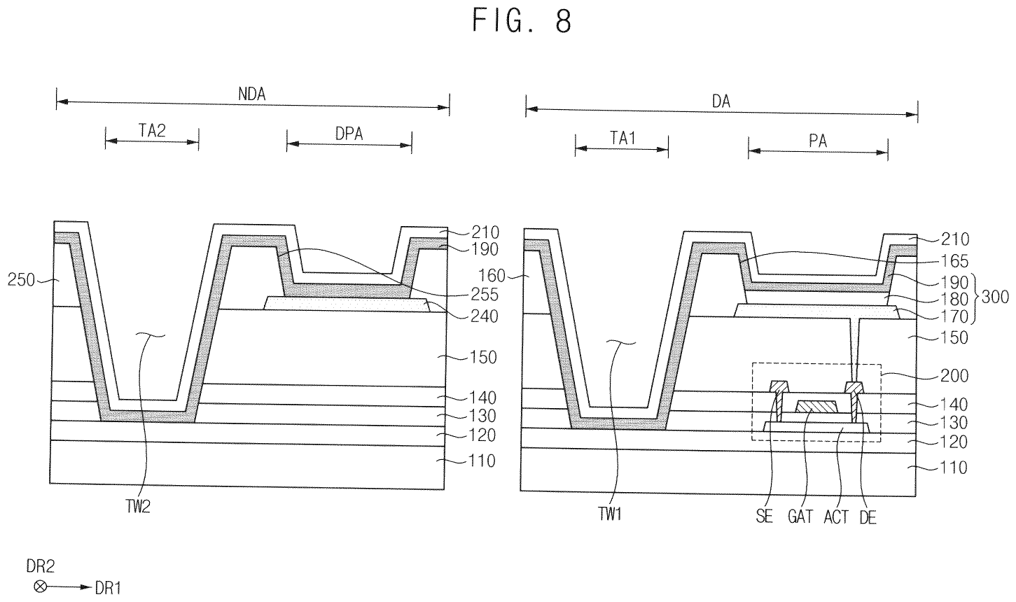

Referring to FIG. 8, the first inorganic encapsulation layer 210 may be provided or formed on the upper electrode 190. The first inorganic encapsulation layer 210 may be entirely formed in the display area DA and the non-display area NDA.

Referring back to FIG. 3, the organic encapsulation layer 220 may be provided or formed on the first inorganic encapsulation layer 210. In addition, the second inorganic encapsulation layer 230 may be provided or formed on the organic encapsulation layer 220. The organic encapsulation layer 220 and the second inorganic encapsulation layer 230 may be entirely formed in the display area DA and the non-display area MDA.

Accordingly, the display device 100 illustrated in FIG. 3 may be manufactured.

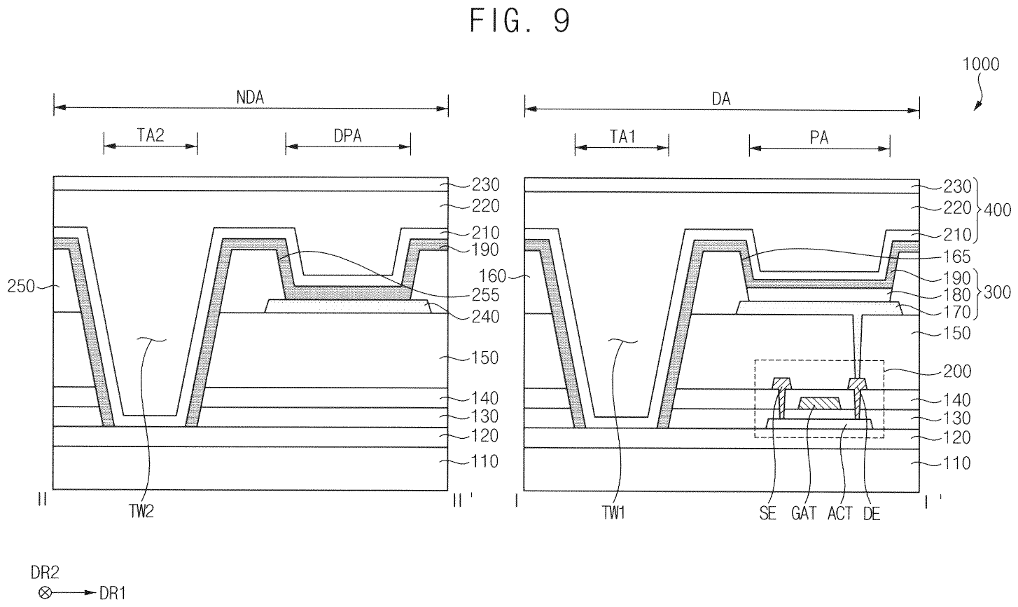

FIG. 9 is a cross-sectional view illustrating a display area and a non-display area of a display device according to an alternative embodiment.

Referring to FIG. 9, a display device 1000 according to an embodiment may include a substrate 110, a buffer layer 120, a semiconductor element 200, a gate insulating layer 130, an interlayer insulating layer 140, a planarization layer 150, a light emitting element 300, a dummy pattern 240, a pixel defining layer 160, a reflection control layer 250, and an encapsulation structure 400. The embodiment of the display device 1000 shown in FIG. 9 may be substantially the same as or similar to the embodiment of the display device 100 described above with reference to FIG. 3 except for a shape of the upper electrode 190. The same or like elements shown in FIG. 9 have been labeled with the same reference characters as used above to describe the embodiment of the display device 100 shown in FIG. 3, and any repetitive detailed description thereof will hereinafter be omitted or simplified.

In such an embodiment, the upper electrode 190 may be disposed in the display area DA on the pixel defining layer 160 and the light emitting layer 180. The upper electrode 190 may extend from the display area DA to the non-display area NDA. In an embodiment, the upper electrode 190 may not overlap each of the first transmission area TA1 and the second transmission area TA2. In such an embodiment, the upper electrode 190 may not be disposed in the first transmission area TA1 and the second transmission area TA2. In such an embodiment, the upper electrode 190 may be entirely disposed in an area other than the first transmission area TA1 and the second transmission area TA2.

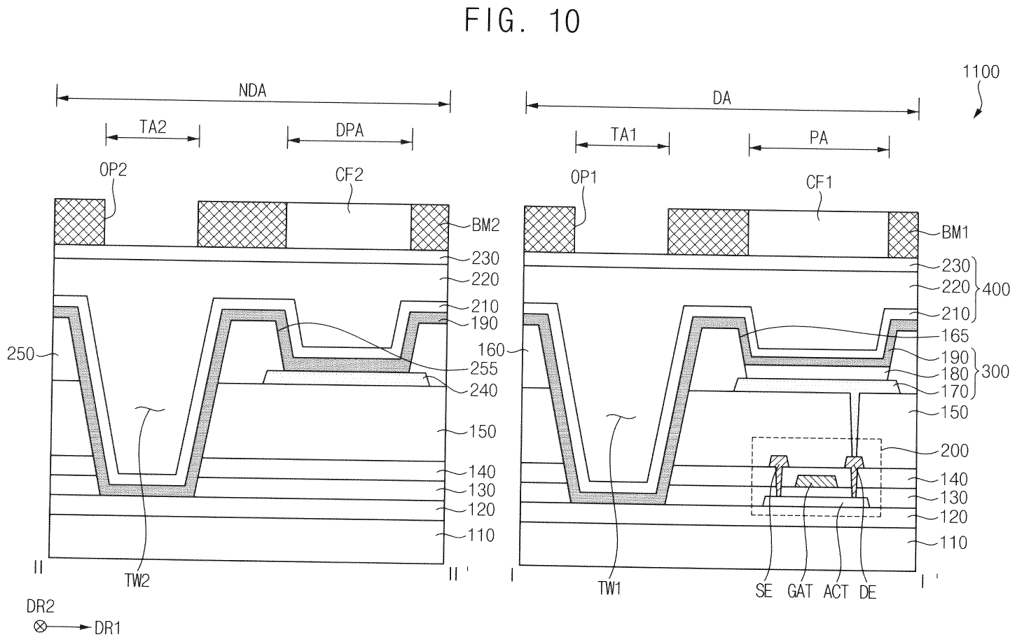

FIG. 10 is a cross-sectional view illustrating a display area and a non-display area of a display device according to another alternative embodiment.

Referring to FIG. 10, a display device 1000 according to an embodiment of the disclosure may include a substrate 110, a buffer layer 120, a semiconductor element 200, a gate insulating layer 130, an interlayer insulating layer 140, a planarization layer 150, a light emitting element 300, a dummy pattern 240, a pixel defining layer 160, a reflection control layer 250, an encapsulation structure 400, a first color filter layer CF1, a second color filter layer CF2, a first light blocking layer BM1, and a second light blocking layer BM2. The embodiment of the display device 1100 show in FIG. 10 may be substantially the same or similar as the embodiment of the display device 100 described above with reference to FIG. 3 except that the display device 1100 further includes the color filter layers CF1 and CF2 and the light blocking layers BM1 and BM2. The same or like elements shown in FIG. 10 have been labeled with the same reference characters as used above to describe the embodiment of the display device 100 shown in FIG. 3, and any repetitive detailed description thereof will hereinafter be omitted or simplified.

In such an embodiment, the first light blocking layer BM1 may be disposed in the display area DA on the encapsulation structure 400. In addition, the second light blocking layer BM2 may be disposed in the non-display area NDA on the encapsulation structure 400. A first opening OP1 overlapping the first transmission area TA1 and the pixel area PA may be defined in the first light blocking layer BM1. In addition, a second opening OP2 overlapping the second transmission area TA2 and the dummy pixel area DPA may be defined in the second light blocking layer BM2.

The size of the first opening OP1 overlapping the pixel area PA may be different from the size of the second opening OP2 overlapping the dummy pixel area DPA. In an embodiment, for example, the size of the second opening OP2 overlapping the dummy pixel area DPA may be smaller than the size of the first opening OP1 overlapping the pixel area PA. As the size of the second opening OP2 overlapping the dummy pixel area DPA is adjusted, the reflectance of the display device 100 from external light in the non-display area NDA may be reduced. Accordingly, the reflectance by external light of the display device 100 in the display area DA may be similar to the reflectance by external light of the display device 100 in the non-display area NDA.

Each of the first light blocking layer BM1 and the second light blocking layer BM2 may be a black matrix. In an embodiment, for example, each of the first light blocking layer BM1 and the second light blocking layer BM2 may include an organic material including a black pigment or a black dye. The first light blocking layer BM1 and the second light blocking layer BM2 may prevent light leakage.

The first color filter layer CF1 may be disposed in the pixel area PA on the encapsulation structure 400, and the second color filter layer CF2 may be disposed in the dummy pixel area DPA on the encapsulation structure 400. In such an embodiment, the first color filter layer CF1 may be disposed in the first opening OP1 of the first light blocking layer BM1, and the second color filter layer CF2 may be disposed in the second opening OP2 of the second light blocking layer BM2. In an embodiment, for example, each of the first color filter layer CF1 and the second color filter layer CF2 may include any one of a red color filter, a green color filter, and a blue color filter. The first color filter layer CF1 may selectively transmit light emitted from the light emitting element 300.

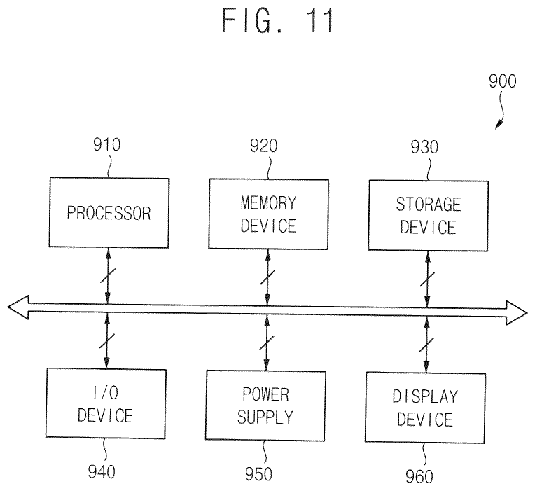

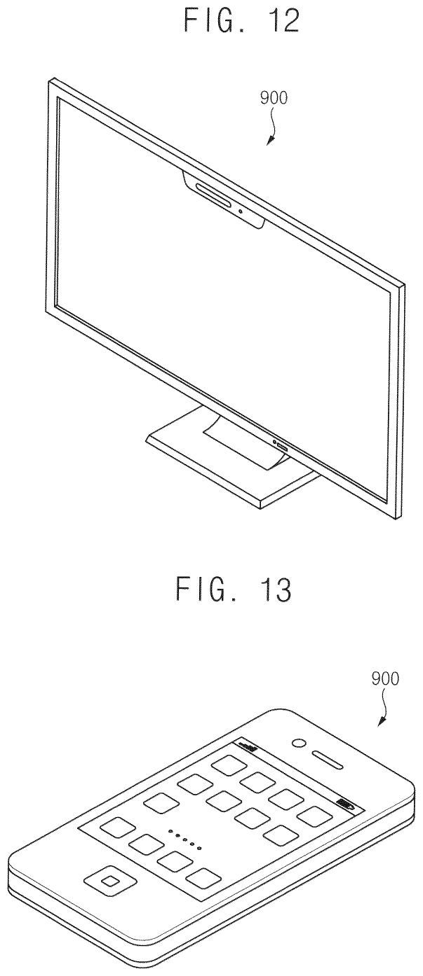

FIG. 11 is a block diagram illustrating an embodiment of an electronic device including the display device of FIG. 1. FIG. 12 is a diagram illustrating an embodiment in which the electronic device of FIG. 11 is implemented as a television. FIG. 13 is a diagram illustrating an embodiment in which the electronic device of FIG. 11 is implemented as a smartphone.

Referring to FIGS. 11, 12 and 13, in an embodiment, the electronic device 900 may include a processor 910, a memory device 920, a storage device 930, an input/output (“I/O”) device 940, a power supply 950 and a display device 960. In this case, the display device 960 may correspond to the display device 100 described with reference to FIGS. 1, 2, and 3. The electronic device 900 may further include various ports capable of communicating with a video card, a sound card, a memory card, a USB device, or the like.

In an embodiment, as illustrated in FIG. 12, the electronic device 900 may be implemented as a television. In an alternative embodiment, as illustrated in FIG. 13, the electronic device 900 may be implemented as a smart phone. However, embodiments are not limited thereto, in another alternative embodiment, the electronic device 900 may be implemented as a cellular phone, a video phone, a smart pad, a smart watch, a tablet personal computer (“PC”), a car navigation system, a computer monitor, a laptop computer, a head disposed (e.g., mounted) display (“HMD”), or the like.

The processor 910 may perform various computing functions. In an embodiment, the processor 910 may be a microprocessor, a central processing unit (“CPU”), an application processor (“AP”), or the like. The processor 910 may be coupled to other components via an address bus, a control bus, a data bus, or the like. The processor 910 may be coupled to an extended bus such as a peripheral component interconnection (“PCI”) bus.

The memory device 920 may store data for operations of the electronic device 900. In an embodiment, the memory device 920 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

The storage device 930 may include a solid state drive (“SSD”) device, a hard disk drive (“HDD”) device, a CD-ROM device, or the like. The I/O device 940 may include an input device such as a keyboard, a keypad, a mouse device, a touchpad, a touch-screen, or the like, and an output device such as a printer, a speaker, or the like.

The power supply 950 may provide power for operations of the electronic device 900. The display device 960 may be coupled to other components via the buses or other communication links. In an embodiment, the display device 960 may be included in the I/O device 940.

Embodiments of the disclosure may be applied to various display devices such as display devices for vehicles, ships and aircraft, portable communication devices, display devices for exhibition or information transmission, medical display devices, or the like.

The invention should not be construed as being limited to the embodiments set forth herein. Rather, these embodiments are provided so that this disclosure will be thorough and complete and will fully convey the concept of the invention to those skilled in the art. While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate including a display area including a first transmission area and a pixel area, and a non-display area including a second transmission area and a dummy pixel area;
a light emitting element including a lower electrode disposed in the pixel area on the substrate;
a dummy pattern disposed in the dummy pixel area on the substrate and including a same material as the lower electrode;
a pixel defining layer disposed in the display area on the substrate and the lower electrode, wherein a first opening exposing an upper surface of the lower electrode is defined in the pixel defining layer; and
a reflection control layer disposed in the non-display area on the substrate and the dummy pattern and including a same material as the pixel defining layer, wherein a second opening exposing an upper surface of the dummy pattern is defined in the reflection control layer.

2. The display device of claim 1, wherein each of the pixel defining layer and the reflection control layer includes an organic insulating material.

3. The display device of claim 2, wherein each of the pixel defining layer and the reflection control layer further includes at least one selected from a black pigment, a black dye, and a carbon black.

4. The display device of claim 1, wherein an area of the first transmission area is the same as an area of the second transmission area.

5. The display device of claim 1, wherein a size of the first opening of the pixel defining layer is different from a size of the second opening of the reflection control layer.

6. The display device of claim 1, wherein the light emitting element further includes:
a light emitting layer disposed in the pixel area on the lower electrode; and
an upper electrode disposed on the pixel defining layer and the light emitting layer.

7. The display device of claim 6, wherein the upper electrode is entirely disposed in the display area and the non-display area.

8. The display device of claim 6, wherein the upper electrode is disposed in an area other than the first transmission area and the second transmission area.

9. The display device of claim 6, further comprising:
an encapsulation structure disposed in the display area and the non-display area on the upper electrode, wherein the encapsulation structure includes an inorganic encapsulation layer and an organic encapsulation layer.

10. The display device of claim 9, further comprising:
a first light blocking layer disposed in the display area on the encapsulation structure, wherein a first opening overlapping each of the first transmission area and the pixel area is defined in the first light blocking layer; and
a first color filter layer disposed in the first opening of the first light blocking layer overlapping the pixel area.

11. The display device of claim 10, further comprising:
a second light blocking layer disposed in the non-display area on the encapsulation structure, wherein a second opening overlapping each of the second transmission area and the dummy pixel area is defined in the second light blocking layer; and
a second color filter layer disposed in the second opening of the second light blocking layer overlapping the dummy pixel area.

12. The display device of claim 11, a size of the first opening of the first light blocking layer overlapping the pixel area is different from a size of the second opening of the second light blocking layer overlapping the dummy pixel area.

13. The display device of claim 1, further comprising:
a buffer layer disposed in the display area and the non-display area on the substrate;
an insulating layer disposed in the display area and the non-display area on the buffer layer; and
a planarization layer disposed in the display area and the non-display area on the insulating layer.

14. The display device of claim 13, wherein the planarization layer includes at least one selected from a photo sensitive polyimide and a siloxane-based resin.

15. The display device of claim 13, wherein a first transmission window exposing an upper surface of the buffer layer positioned in the first transmission area is defined through the insulating layer, the planarization layer and the pixel defining layer, and
wherein a second transmission window exposing an upper surface of the buffer layer positioned in the second transmission area is defined through the insulating layer, the planarization layer, and the reflection control layer.

16. The display device of claim 1, wherein the dummy pattern has an island shape in a plan view.

17. The display device of claim 1, wherein each of the pixel area and the dummy pixel area is repeatedly arranged in a first direction and a second direction orthogonal to the first direction.

18. The display device of claim 17, wherein the first transmission area is arranged on a side of the pixel area, and the second transmission area is arranged on a side of the dummy pixel area.

19. A display device comprising:
a substrate including a display area including a first transmission area and a pixel area, and a non-display area including a second transmission area and a dummy pixel area, wherein the second transmission area has a same area as an area of the first transmission area;
a light emitting element including a lower electrode disposed in the pixel area on the substrate;
a dummy pattern disposed in the dummy pixel area on the substrate and disposed in a same layer as the lower electrode;
a pixel defining layer disposed in the display area on the substrate and the lower electrode and having a black color; and
a reflection control layer disposed in the non-display area on the substrate and the dummy pattern, and disposed in a same layer as the pixel defining layer.

20. The display device of claim 19, wherein a first opening exposing an upper surface of the lower electrode is defined in the pixel defining layer, and a second opening exposing an upper surface of the dummy pattern is defined in the reflection control layer, and
wherein a size of the first opening of the pixel defining layer is different from a size of the second opening of the reflection control layer.
